(19) United States
(12) Patent Application Publication
(10) Pub. No.: US 2015/0303094 A1
(43) Pub. Date: Oct. 22, 2015

(54) APPARATUS AND METHOD FOR TREATING SUBSTRATE

(71) Applicant: PKS INC., Hwaseong-si (KR)

(72) Inventor: Byoung Hoon KIM, Hwaseong-si (KR)

(21) Appl. No.: 14/576,822

(22) Filed: Dec. 19, 2014

(30) Foreign Application Priority Data
Apr. 22, 2014 (KR) 10-2014-0048143

(51) Int. Cl. H01L 21/687; H01L 21/67; H01L 21/3065

(52) U.S. Cl. CPC H01L 21/68707; H01L 21/3065; H01L 21/67207; H01L 21/67063; H01L 21/67028; H01L 21/67201

(57) ABSTRACT

Provided are an apparatus and method for treating a substrate. The apparatus for treating the substrate includes a process module including a main process chamber in which main treatment step is performed on the substrate, an index module including a loadport on which a container for accommodating the substrate is placed, an auxiliary process chamber in which auxiliary treating is performed on the substrate, and an index robot for transferring the substrate, and a loadlock chamber disposed between the process module and the index module. The process module, the loadlock chamber, and the auxiliary process chamber are successively disposed in a first direction, and the index robot configured to transfer the substrate into each of the loadport, the auxiliary process chamber, and the loadlock chamber.

### CROSS-REFERENCE TO RELATED APPLICATIONS

This U.S. non-provisional patent application claims priority under 35 U.S.C. §119 of Korean Patent Application No. 10-2014-0048143, filed on Apr. 22, 2014, the entire contents of which are hereby incorporated by reference.

### BACKGROUND OF THE INVENTION

The present invention disclosed herein relates to an apparatus and method for treating a substrate, and more particularly, to an apparatus for treating a substrate, which performs a plurality of treatment processes and a method for treating the substrate by using the same.

Semiconductor devices are manufactured by forming a circuit pattern on a substrate such as a wafer through various processes such as deposition, photographing, etching, ashing, and cleaning processes. These processes are performed in each of chambers that are provided to perform corresponding processes. Thus, in the processes for manufacturing semiconductor devices, a process of loading a substrate into a chamber and a process of loading the substrate into the other chamber for performing the other process are repeatedly performed.

In recent years, as semiconductor devices are miniaturized, more processes for manufacturing semiconductor devices are needed. Accordingly, a period of time that takes to transfer a substrate between chambers in the total time for manufacturing the semiconductor devices is increasing more and more.

### SUMMARY OF THE INVENTION

The present invention provides an apparatus for treating a substrate, which is capable of minimizing a time that takes to treat a substrate through efficient substrate transfer and a method for treating the substrate.

The present invention also provides an apparatus for treating a substrate, which provides at least one process chamber to perform various processes and a method for treating the substrate.

The object of the present invention is not limited to the aforesaid, but other objects not described herein will be clearly understood by those skilled in the art from descriptions below.

The present invention provides an apparatus for treating a substrate.

Embodiments of the present invention provide apparatuses for treating a substrate, including: a process module including a main process chamber in which main treatment step is performed on the substrate; an index module including a loadport on which a container for accommodating the substrate is placed, an auxiliary process chamber in which auxiliary treating is performed on the substrate, and an index robot for transferring the substrate; and a loadlock chamber disposed between the process module and the index module, wherein the process module, the loadlock chamber, and the auxiliary process chamber are successively disposed in a first direction, and the index robot configured to transfer the substrate into each of the loadport, the auxiliary process chamber, and the loadlock chamber.

In some embodiments, the index module may include a guide lengthily disposed in the first direction, and the index robot is movable along the guide.

In other embodiments, the main process chamber may have a structure in which a dry cleaning process is capable of being performed.

In still other embodiments, the main process chamber may have a structure in which a dry etching process is capable of being performed.

In even other embodiments, the loadlock chamber may include: a buffer unit in which the substrate stays when the substrate is transferred between the auxiliary process chamber and the process module; and a cooling unit for cooling the substrate.

In yet other embodiments, the buffer unit and the cooling unit may be vertically stacked on each other.

In further embodiments, the auxiliary process chamber may include a heat treatment chamber in which a heat treatment process is performed on the substrate.

In still further embodiments, the auxiliary process chamber may include a wet clean chamber in which a wet cleaning process is performed on the substrate.

In even further embodiments, the auxiliary process chamber may include a heat treatment chamber in which an ashing process is performed on the substrate.

In yet further embodiments, the auxiliary process chamber may include: a heat treatment chamber in which a heat treatment process is performed on the substrate; and a wet clean chamber in which a wet cleaning process is performed on the substrate.

In much further embodiments, the auxiliary process chamber may include: a heat treatment chamber in which an ashing process is performed on the substrate; and a wet clean chamber in which a wet cleaning process is performed on the substrate.

In still much further embodiments, each of the loadlock chamber and the auxiliary process chamber may be provided in plurality, and the loadlock chambers may be disposed on one side and the other side in the first direction with respect to the index robot, and the auxiliary process chambers may be disposed on one side and the other sides in the first direction with respect to the index robot.

In even much further embodiments, the loadlock chambers may be arranged in a second direction perpendicular to the first direction, and the auxiliary process chambers may be arranged in the second direction.

In yet much further embodiments, the process module may further include a transfer chamber in which a transfer robot for transferring the substrate is disposed, and the main process chamber and the loadlock chamber may be disposed around the transfer chamber.

In much still further embodiments, the heat treatment chamber may include: a housing; a substrate support unit disposed within the housing to support the substrate; a gas supply unit supplying a gas into the housing; a plasma source generating plasma from the gas; and a heating unit disposed in the substrate support unit to heat the substrate.

In other embodiments of the present invention, apparatuses for treating a substrate include: a process module including a main process chamber in which main treatment step is performed on the substrate and a transfer chamber for transferring the substrate; an index module including a loadport on which a container for accommodating the substrate is placed, an auxiliary process chamber in which auxiliary treating is performed on the substrate, and an index robot for transferring the substrate; and a loadlock chamber disposed between the process module and the index module, wherein the loadlock chamber is disposed on each of both side surfaces of the index robot, the loadlock chamber includes a first loadlock chamber and a second loadlock chamber, the auxiliary process chamber includes a first auxiliary process chamber and a second auxiliary process chamber, the first loadlock chamber is disposed on one side of the index robot, the second loadlock chamber is disposed on the other side of the index robot, the first auxiliary process chamber and the first loadlock chamber disposed on the one side of the index robot are disposed in the first direction; the second auxiliary process chamber and the second loadlock chamber disposed on the other side of the index robot are disposed in the first direction; the first loadlock chamber, the first auxiliary process chamber, and the loadport are successively disposed in the first direction; the second loadlock chamber, the second auxiliary process chamber, and the loadport are successively disposed in the first direction; the index robot configured to transfer the substrate into the first loadlock chamber, the second loadlock chamber, the first auxiliary process chamber, the second auxiliary process chamber, and a container placed on the loadport, the first auxiliary process chamber is provided as a heat treatment chamber in which a heat treatment process is performed on the substrate; and the second auxiliary process chamber is provided as a wet clean chamber in which a wet cleaning process is performed on the substrate.

In some embodiments, the index module may include a guide lengthily disposed in the first direction, and the index robot is movable along the guide.

The present invention also provides a method for treating a substrate.

In still other embodiments of the present invention, methods for treating a substrate include: treating the substrate in a selected mode of a plurality of modes according to a state of the substrate, wherein, in the plurality of modes, processes for treating the substrate are different from each other.

In some embodiments, the plurality of modes may include a first treatment mode, and the first treatment mode may include: a main treatment step of performing a dry cleaning process or dry etching process on the substrate in the main process chamber; and a film removal step including a byproduct removal process for removing byproducts remaining on the substrate in the auxiliary process chamber after the main treatment step.

In other embodiments, in the first treatment mode, the film removal step may include a wet cleaning step of performing a wet cleaning process in the wet clean chamber.

In still other embodiments, in the first treatment mode, the film removal step may include a heat treatment step of performing a heat treatment process in the heat treatment chamber.

In even other embodiments, in the first treatment mode, the film removal step may include: a heat treatment step of performing a heat treatment process in the heat treatment chamber; and a wet cleaning step of performing a wet cleaning process in the wet clean chamber.

In yet other embodiments, the plurality of modes may include a second treatment mode, and the second treatment mode may include: a surface treatment step of converting a surface of the substrate into a hydrophilic or hydrophobic surface in the auxiliary process chamber; a main treatment step of performing a dry cleaning process or dry etching process on the substrate in the main process chamber; and a film removal step including a byproduct removal process for removing byproducts remaining on the substrate in the auxiliary process chamber after the main treatment step.

In further embodiments, in the second treatment mode, the film removal step may include a wet cleaning step of performing a wet cleaning process in the wet clean chamber.

In still further embodiments, in the second treatment mode, the film removal step may include a heat treatment step of performing a heat treatment process in the heat treatment chamber.

In even further embodiments, in the second treatment mode, the heat treatment chamber may have a structure in which a gas for converting a surface of the substrate into a hydrophilic or hydrophobic surface is supplied, and the surface treatment step may be performed in the heat treatment chamber.

In yet further embodiments, in the second treatment mode, the wet clean chamber may have a structure in which a chemical solution for a surface of the substrate into a hydrophilic or hydrophobic surface in the auxiliary process chamber, and the surface treatment step may be performed in the wet clean chamber.

In much further embodiments, the auxiliary process chamber may have a structure in which an ashing process is capable of being performed, the plurality modes may include a third treatment mode, and the third treatment mode may include: an ashing step of performing an ashing process in the auxiliary process chamber; and a main treatment step of performing a dry cleaning process or dry etching process on the substrate in the main process chamber.

In still much further embodiments, in the third treatment mode, the methods may further include a film removal step including a byproduct removal process for removing reaction byproducts remaining on the substrate in the auxiliary process chamber after the main treatment step.

In even much further embodiments, the auxiliary process chamber may have a structure in which an ashing process is capable of being performed, and the plurality of modes may include at least two modes of: a first treatment mode including a main treatment step of performing a dry cleaning process or dry etching process on the substrate in the main process chamber and a film removal step including a byproduct removal process for removing reaction byproducts remaining on the substrate in the auxiliary process chamber after the main treatment step; a second treatment mode including a surface treatment step of converting a surface of the substrate into a hydrophilic or hydrophobic surface in the auxiliary process chamber, a main treatment step of performing a dry cleaning process or dry etching process on the substrate in the main process chamber, and a film removal step including a byproduct removal process for removing byproducts remaining on the substrate in the auxiliary process chamber after the main treatment step; a third treatment mode an ashing step of performing an ashing process in the auxiliary process chamber and a main treatment step of performing a dry cleaning process or dry etching process on the substrate in the main process chamber; and a fourth treatment mode including an ashing step of performing an ashing process in the heat treatment chamber and a wet cleaning step of performing a wet cleaning process in the wet cleaning chamber.

### BRIEF DESCRIPTION OF THE DRAWINGS

The accompanying drawings are included to provide a further understanding of the present invention, and are incorporated in and constitute a part of this specification. The drawings illustrate exemplary embodiments of the present invention and, together with the description, serve to explain principles of the present invention. In the drawings:

FIG. 1 is a plan view of a substrate treatment apparatus according to an embodiment of the present invention;

FIG. 2 is a cross-sectional view of a loadlock chamber of FIG. 1, taken along line A-A;

FIG. 3 is a cross-sectional view illustrating a modified example of the loadlock chamber of FIG. 1;

FIG. 4 is a cross-sectional view of a heat treatment chamber that is provided as an auxiliary process chamber according to an embodiment of the present invention;

FIG. 5 is a cross-sectional view of a wet clean chamber that is provided as an auxiliary process chamber according to an embodiment of the present invention;

FIG. 6 is a plan view illustrating a modified example of the substrate treatment apparatus of FIG. 1;

FIG. 7 is a plan view illustrating another modified example of the substrate treatment apparatus of FIG. 1;

FIG. 8 is a plan view illustrating further another modified example of the substrate treatment apparatus of FIG. 1;

FIG. 9 is a cross-sectional view of a heat treatment chamber that is provided as an auxiliary process chamber according to another embodiment of the present invention;

FIG. 10 is a view of a substrate transfer path in a first treatment mode in a substrate treatment apparatus according to an embodiment of the present invention;

FIG. 11 is a view of a substrate transfer path in a first treatment mode in a substrate treatment apparatus according to another embodiment of the present invention;

FIG. 12 is a view of a substrate transfer path in a first treatment mode in a substrate treatment apparatus according to further another embodiment of the present invention;

FIG. 13 is a view of a substrate transfer path in a second treatment mode in the substrate treatment apparatus according to an embodiment of the present invention;

FIG. 14 is a view of a substrate transfer path in a second treatment mode in the substrate treatment apparatus according to another embodiment of the present invention;

FIG. 15 is a view of a substrate transfer path in a third treatment mode in the substrate treatment apparatus according to an embodiment of the present invention;

FIG. 16 is a view of a substrate transfer path in a third treatment mode in the substrate treatment apparatus according to another embodiment of the present invention;

FIG. 17 is a view of a substrate transfer path in a third treatment mode in the substrate treatment apparatus according to further another embodiment of the present invention; and

FIG. 18 is a view of a substrate transfer path in a fourth treatment mode in the substrate treatment apparatus.

### DETAILED DESCRIPTION OF PREFERRED EMBODIMENTS

Preferred embodiments of the present invention will be described below in more detail with reference to the accompanying drawings. The present invention may, however, be embodied in different forms and should not be constructed as limited to the embodiments set forth herein. Rather, these embodiments are provided so that this disclosure will be thorough and complete, and will fully convey the scope of the present invention to those skilled in the art. In the drawings, the thicknesses of layers and regions are exaggerated for clarity.

A substrate treatment apparatus may perform a plurality of treatment processes on the substrate. The substrate may be a substrate that is used for manufacturing flat panel displays (FPDs) and other objects in which a circuit is formed on a thin film. The treatment processes may be various processes required for manufacturing semiconductor devices, FPDs, and other objects in which a circuit is formed on a thin film. For example, the substrate may include a wafer or a glass substrate.

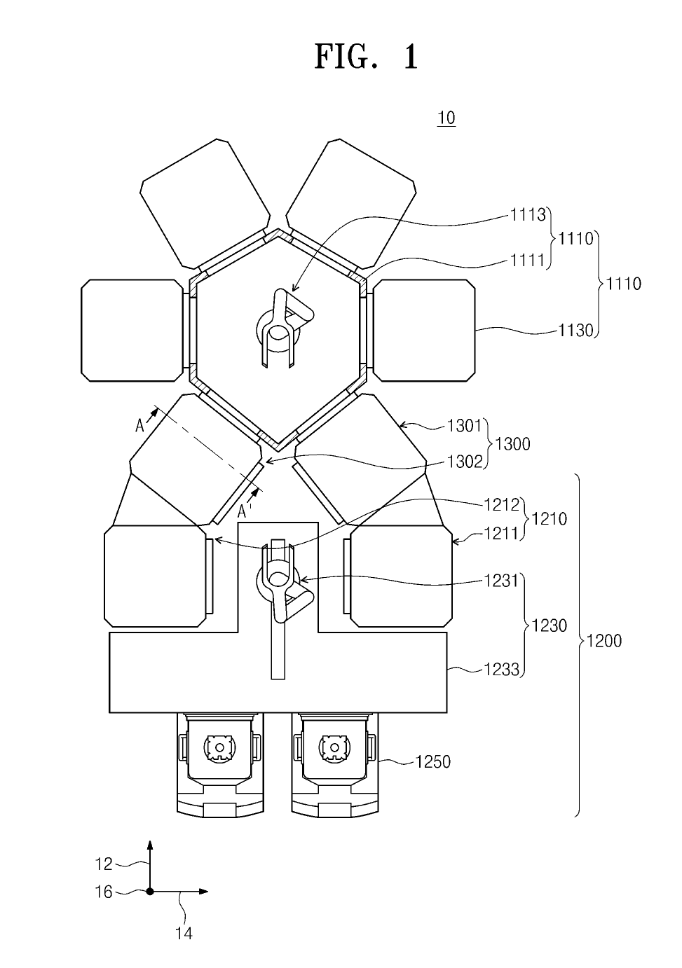

FIG. 1 is a plan view of a substrate treatment apparatus according to an embodiment of the present invention.

Referring to FIG. 1, an apparatus 10 for treating a substrate includes a process module 1100, a loadlock chamber 1300, and an index module 1200. The process module 1100, the loadlock chamber 1300, and the index module 1200 are successively arranged in a line. Here, a direction in which the process module 1100, the loadlock chamber 1300, and the index module 1200 are arranged is referred to as a first direction 12. When viewed from above, a direction perpendicular to the first direction 12 is referred to as a second direction 14. Also, a direction perpendicular to each of the first and second directions 12 and 14 is referred to as a third direction 16.

The process module 1100 includes a main process chamber 1130 and a transfer chamber 1110. The process module 1100 performs a main process on a substrate.

The transfer chamber 1110 is disposed adjacent to the loadlock chamber 1300. The transfer chamber 1110 includes a housing 1111 and a transfer robot 1113. The housing 1111 may have a polygonal shape when viewed from above. The housing 1111 having a hexagonal shape may be provided as an example. Alternatively, the transfer chamber 1110 may have various shapes.

For example, loadlock chambers 1300 and a plurality of main process chambers 1130 may be disposed adjacent to the outside of the housing 1111. A passage through which a substrate is loaded or unloaded between the transfer chamber 1110 and the loadlock chamber 1300 or between the transfer chamber 1110 and the main process chamber 1130 is defined in each of sidewalls of the housing 1111. A door for opening or closing the passage is disposed on the passage.

The transfer robot 1113 is disposed within the transfer chamber 1110. The transfer robot 1113 may transfer a non-treated substrate that stays in the loadlock chamber 1300 into the main process chamber 1130 or transfer the treated substrate into the loadlock chamber 1300.

The main process chamber 1130 is disposed adjacent to the transfer chamber 1110. According to an embodiment, the main process chamber 1130 may be provided in plurality on side portions of the housing 1111 of the transfer chamber 1110. For example, four main process chambers 1130 may be provided. When the four main process chambers 1130 are provided, the four main process chambers 1130 may be successively disposed along the adjacent side surfaces of the transfer chamber 1110. The main process chamber 1130 may have a structure in which a process for treating a substrate by using plasma such as a dry cleaning process or wet etching process is capable of being performed on the substrate.

The loadlock chamber 1300 is disposed between the process module 1100 and the index module 1200. For example, two loadlock chambers 1300 may be provided. Hereinafter, the two loadlock chambers 1300 are called a first loadlock chamber 1301 and a second loadlock chamber 1302. The first and second loadlock chambers 1301 and 1302 are disposed adjacent to the transfer chamber 1110. Each of the loadlock chambers 1300 may be lengthily disposed inclined with respect to the first direction 12. Also, an index robot 1231 is disposed between the first loadlock chamber 1301 and the second loadlock chamber 1302.

The inside of each of the transfer chamber 1110 and the main process chamber 1130 may be maintained in a vacuum state, and the inside of the loadlock chamber 1300 may be converted between a vacuum state and an atmosphere state.

For example, the first loadlock chamber 1301 may have the same structure as the second loadlock chamber 1302.

The loadlock chamber 1300 may include a buffer unit 1330 and a cooling unit 1310.

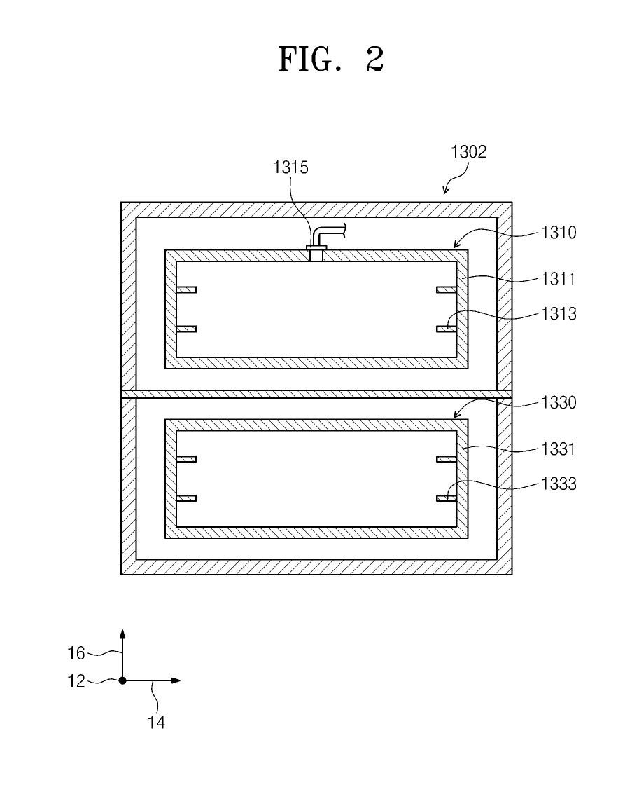

FIG. 2 is a cross-sectional view of the loadlock chamber 1302 of FIG. 1, taken along line A-A. The buffer unit 1330 and the cooling unit 1310 may be stacked on each other. For example, the buffer unit 1330 may be disposed above the cooling unit 1310. For another example, the cooling unit 1310 may be disposed above the buffer unit 1330.

The buffer unit 1330 provides a space in which the substrate transferred from the index module 1200 to the process module 1100 temporarily stays. The inside of the buffer unit 1330 may be converted between a vacuum pressure and an atmospheric pressure.

The buffer unit 1330 includes a housing 1331 and a support plate 1333. The support plate 1333 is disposed within the housing 1331. The support plate 1333 is provided in plurality. The support plates 1333 are stacked on each other. The support plates 1333 may support both edges of the substrate.

The cooling unit 1310 cools the substrate transferred from the process module 1100 to the index module 1200. The inside of the cooling unit 1310 may be converted between a vacuum pressure and an atmospheric pressure.

The cooling unit 1310 includes a housing 1311, a support plates 1313, and a gas supply unit 1315. The support plate 1313 may be provided in plurality within the housing 1311. The support plates 1313 are stacked on each other. The support plates 1313 may support both edges of the substrate. The gas supply unit 1315 may be disposed in an inner upper portion of the housing 1311. The gas supply unit 1315 supplies a cooling gas for cooling the substrate.

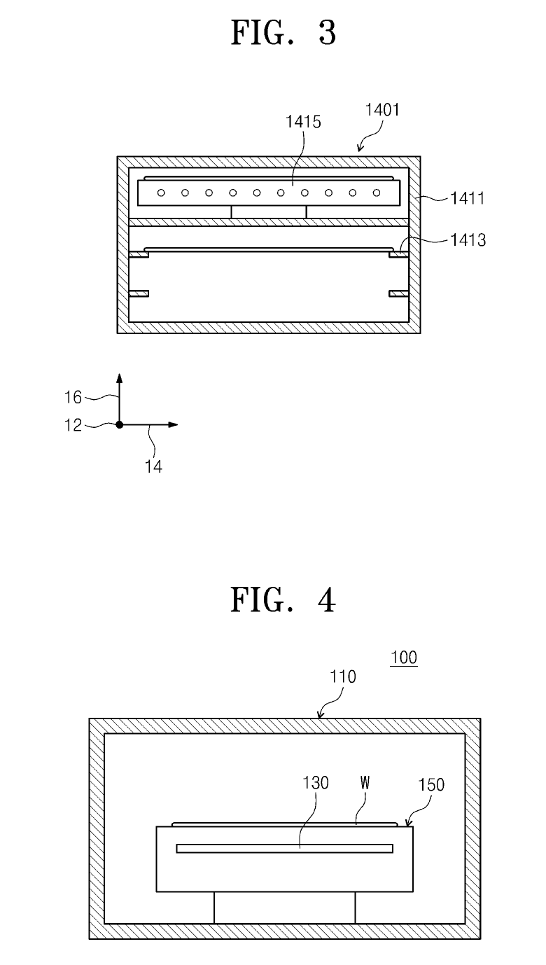

FIG. 3 is a cross-sectional view illustrating a modified example of the loadlock chamber of FIG. 1.

A loadlock chamber 1401 includes a housing 1411, a support plate 1413, and a cooling member 1415. The support plate 1413 is disposed within the housing 1411. The support plate 1413 has a plate shape. The cooling member 1415 is disposed inside the support plate 1413. The cooling member 1415 may be provided as a cooling line through which a cooling fluid flows.

Unlike the foregoing embodiment, each of first and second loadlock chambers 1301 and 1302 may be formed by stacking units having the same structure on each other. For example, the first loadlock chamber 1301 may be formed by stacking a plurality of buffer units 1330 on each other. Also, the second loadlock chamber 1302 may be formed by stacking a plurality of cooling units 1310 on each other.

The index module 1200 includes an auxiliary process chamber 1210, a transfer frame 1230, and a loadport 1250. According to an embodiment, two auxiliary process chambers 1210 may be provided. Hereinafter, the two auxiliary process chambers are called a first auxiliary process chamber 1211 and a second auxiliary process chamber 1212. The auxiliary process chamber 1210 is disposed between the loadlock chamber 1300 and the loadport 1250. The first loadlock chamber 1301, the first auxiliary process chamber 1211, and the loadport 1250 are successively arranged in the first direction 12. The second loadlock chamber 1302, the second auxiliary process chamber 1212, and the loadport 1250 are successively arranged in the first direction 12.

The auxiliary process chamber 1210 includes a heat treatment chamber and a wet clean chamber. According to an embodiment, the first auxiliary process chamber 1211 may be provided as the heat treatment chamber, and the second auxiliary process chamber 1212 may be provided as the wet clean chamber.

FIG. 4 is a cross-sectional view of a heat treatment chamber 100 that is provided as the auxiliary process chamber according to an embodiment of the present invention.

The heat treatment chamber 100 includes a housing 110, a heating unit 130, and a substrate support member 150. The substrate support member 150 is disposed within the housing 110. The heating unit 130 is disposed within the substrate support member 150. The heat treatment chamber 100 performs a heat treatment process on a substrate.

According to another embodiment, the heat treatment chamber may have a structure in which a surface treatment process is capable of being performed. For example, the heat treatment chamber may include a humidification supply unit for supplying a gas that coverts a surface of the substrate into a hydrophilic or hydrophobic surface. For example, oxygen (O₂) that is capable of converting the surface of the substrate into the hydrophilic surface may be used.

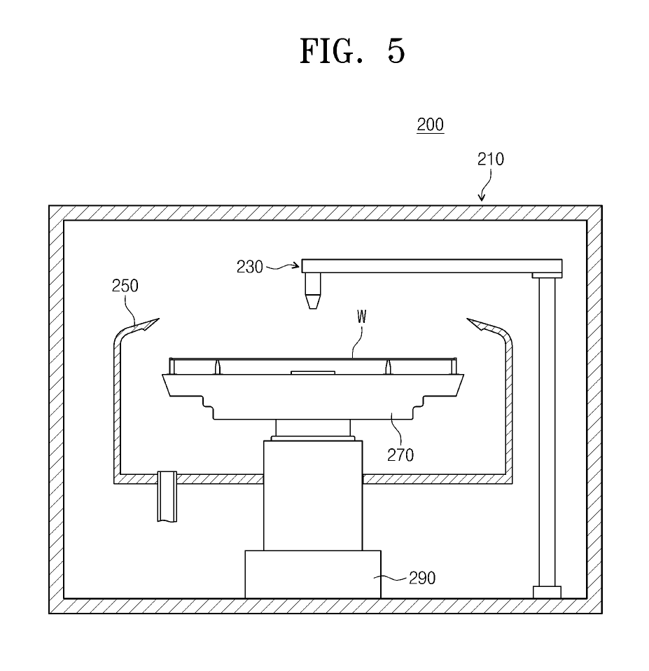

FIG. 5 is a cross-sectional view of the wet clean chamber 200 that is provided as the auxiliary process chamber according to an embodiment of the present invention.

The wet clean chamber 200 includes a housing 210, a cleaning unit 230, a container 250, a support unit 270, and a rotation unit 290. The cleaning unit 230 is disposed within the housing 210. The container 250 may be disposed within the housing 210 and have a shape with an upper portion opened. A portion of the cleaning unit 230 is disposed adjacent to the opened upper portion of the container 250. The support unit 270 is disposed within the container 250. The support unit 270 supports the substrate so that the substrate is placed in a horizontal state. The rotation unit 290 is disposed under the support unit 270 to rotate when the cleaning process is performed on the substrate. The cleaning unit 230 supplies a cleaning solution onto the substrate.

In the wet clean chamber 200, the cleaning solution is supplied onto the substrate to treat the substrate. The cleaning solution that is supplied for cleaning the substrate may include a series of cleaning-related chemical materials including hydrogen fluoride (HF), deionized water (DI-water), ammonia water, and a cleaning solution containing chemical materials such as hydrogen peroxide, water, hydrochloric acid, and hydrogen fluoride.

According to another embodiment, the wet clean chamber may have a structure in which a surface treatment process is capable of being performed. For example, the wet treatment chamber may include a surface treatment unit for supplying a surface treatment solution that coverts a surface of the substrate into a hydrophilic or hydrophobic surface.

The transfer frame 1230 includes an index robot 1231 and a housing 1233.

The index robot 1231 is configured to transfer a substrate into each of the first auxiliary process chamber 1211, the second auxiliary process chamber 1212, the first loadlock chamber 1301, and the second loadlock chamber 1302.

The index robot 1231 is movable vertically. A hand of the index robot 1231 may move forward or backward or rotate on a horizontal plane. The hand may be provided in one or plurality.

According to an embodiment, the housing 1233 includes a first region and a second region. The first region is lengthily defined in the first direction 12, and the second region is lengthily defined in the second direction 14. The first region extends from a space between the first loadlock chamber 1301 and the second loadlock chamber 1302 up to a space between the first auxiliary process chamber 1211 and the second auxiliary process chamber 1212. The second region is defined in an opposite side of the loadlock chamber 1300 with respect to the first auxiliary process chamber 1211. The first region extends from a central region of the second region.

The container is mounted on the loadport 1250. The loadport 1250 is disposed adjacent to the second region.

The container may be transferred from the outside and then loaded or be unloaded from the loadport 1250 and then transferred to the outside. For example, the container may be loaded on the loadport 1250 by a transfer unit such as an overhead hoist transfer. Selectively, the container may be placed on a position adjacent to the loadport 1250 by an automatic guided vehicle, a rail guided vehicle, or a worker.

The container has an accommodation space in which the substrate is accommodated. The accommodation apace of the container may have a sealed structure. A front opening unified pod (FOUP) may be used as the container. The FOUP may accommodate about 25 sheets of substrates therein.

Hereinafter, a substrate treatment method by using the substrate treatment apparatus of FIG. 1 will be described. According to an embodiment, a substrate is treated in a mode selected from a plurality of modes according to a state of the substrate. In the plurality of modes, treatment processes different from each other may be performed on the substrate. The plurality of modes include a first treatment mode S100 and a second treatment mode S200.

The first treatment mode S100 includes a main treatment step and a film removal step. The main treatment step and the film removal step are successively performed. The main treatment step is performed in a main process chamber 1130. A dry cleaning process or dry etching process is performed on a substrate in the main process chamber 1130. The film removal step is performed in an auxiliary process chamber 1210. A film removal process for removing reaction byproducts remaining on the substrate may be performed in the auxiliary process chamber 1210 after the main treatment step.

According to an embodiment, the film removal step in the first treatment mode S100 may be performed in a wet clean chamber. The film removal process may be performed in the wet clean chamber by the wet cleaning process.

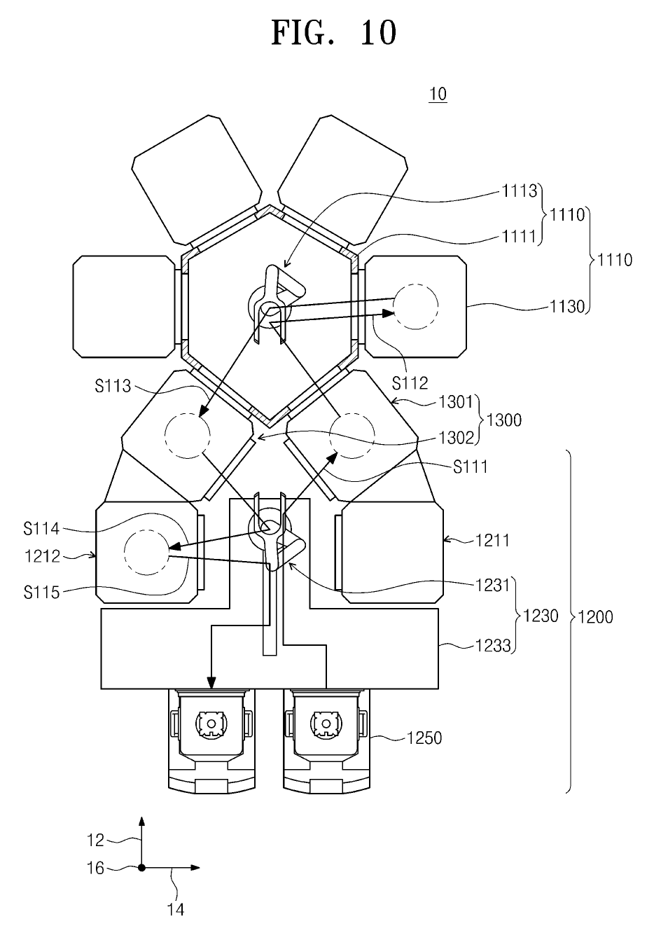

FIG. 10 is a view of a substrate transfer path in the first treatment mode S100 in the substrate treatment apparatus of FIG. 1 according to an embodiment of the present invention. Hereinafter, the substrate transfer path will be described with reference to FIG. 10.

In operation S111, a substrate is transferred from a container placed on a loadport 1250 to a buffer unit 1330 by an index robot 1231. In operation S112, the substrate is transferred from the buffer unit 1330 to a main process chamber 1130 by a transfer robot 1113. A dry cleaning process or dry etching process is performed on the substrate in the main process chamber 1130. In operation S113, the substrate is transferred to a buffer unit 1330 by the transfer robot 1113 after the main treatment step. In operation S114, the substrate is transferred from the buffer unit 1330 to a wet clean chamber 1212 by the index robot 1231. A film removal process may be performed in the wet clean chamber 1212 by a wet cleaning process. In operation S115, the substrate is transferred to the container placed on the loadport 1250 by the index robot 1231 after the film removal step.

According to another embodiment, in the film removal step in the first treatment mode S100, the film removal process may be performed in a heat treatment chamber 1211 by a heat treatment process.

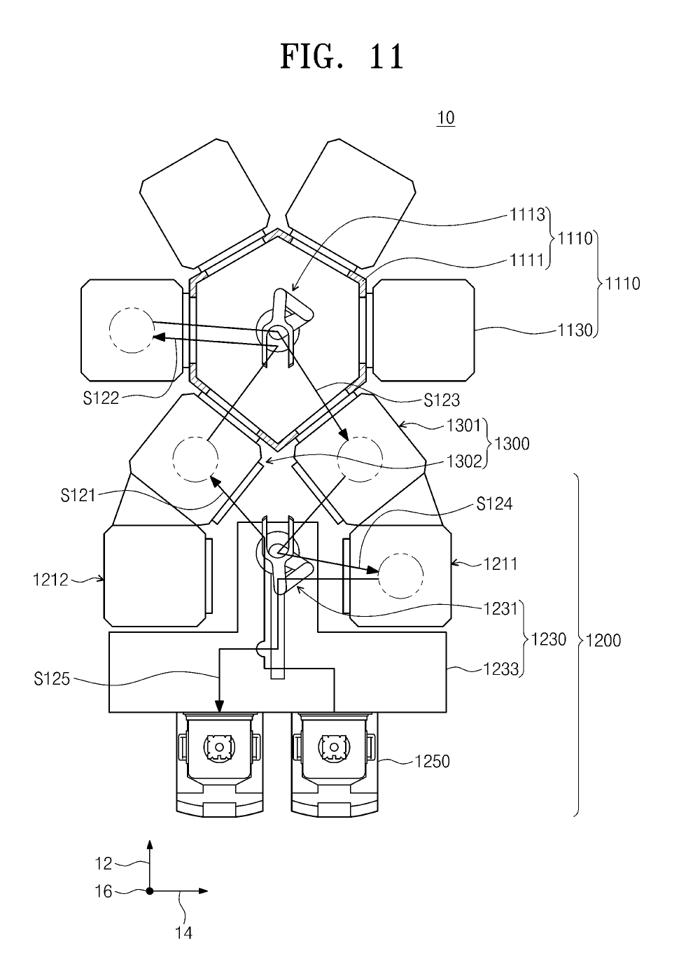

FIG. 11 is a view of a substrate transfer path in the first treatment mode S100 in the substrate treatment apparatus of FIG. 1 according to another embodiment of the present invention. Hereinafter, the substrate transfer path will be described with reference to FIG. 11.

In operation S121, a substrate is transferred from a container placed on a loadport 1250 to a buffer unit 1330 by an index robot 1231. In operation S122, the substrate is transferred from the buffer unit 1330 to a main process chamber 1130 by a transfer robot 1113. A dry cleaning process or dry etching process is performed on the substrate in the main process chamber 1130. In operation S123, the substrate is transferred to a buffer unit 1330 by the transfer robot 1113 after the main treatment step. In operation S124, the substrate is transferred from the buffer unit 1330 to a heat treatment chamber 1211 by the index robot 1231. A film removal process may be performed in the heat treatment chamber 1211 by a heat treatment process. In operation S125, the substrate is transferred to the container placed on the loadport 1250 by the index robot 1231 after the film removal step.

According to another embodiment, in the film removal step in the first treatment mode S100, a film removal process including heat treating that is performed in the heat treatment chamber 1211 by the heat treatment process and wet cleaning that is performed in a wet clean chamber 1212 by a wet cleaning process may be performed.

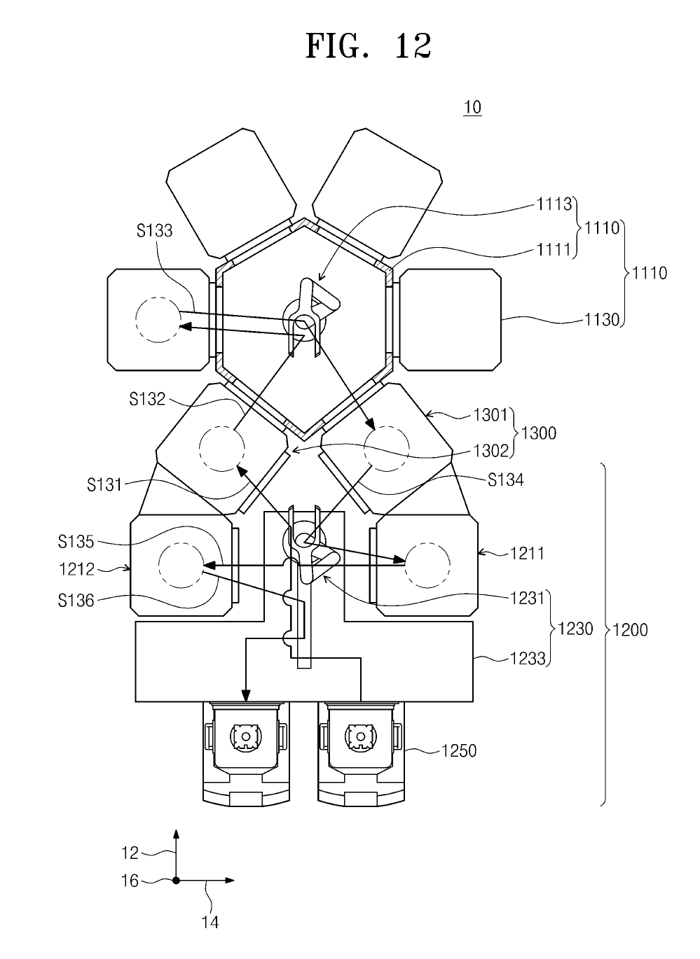

FIG. 12 is a view of a substrate transfer path in the first treatment mode S100 in the substrate treatment apparatus of FIG. 1 according to another embodiment of the present invention. Hereinafter, the substrate transfer path will be described with reference to FIG. 12.

In operation S131, a substrate is transferred from a container placed on a loadport 1250 to a buffer unit 1330 by an index robot 1231. In operation S132, the substrate is transferred from the buffer unit 1330 to a main process chamber 1130 by a transfer robot 1113. A dry cleaning process or dry etching process is performed on the substrate in the main process chamber 1130. In operation S133, the substrate is transferred to a buffer unit 1330 by the transfer robot 1113 after the main treatment step. In operation S134, the substrate is transferred from the buffer unit 1330 to a heat treatment chamber 1211 by the index robot 1231. A heat treatment process may be performed in the heat treatment chamber 1211. In operation S134, the substrate is transferred from the heat treatment chamber 1211 to a wet clean chamber 1212 by the index robot 1231. A film removal process may be performed in the wet clean chamber 1212 by a wet cleaning process. In operation S136, the substrate is transferred to the container placed on the loadport 1250 by the index robot 1231 after the film removal step.

A second treatment mode S200 includes surface treating, main treatment step, and film removal step. The surface treating, the main treatment step, and the film removal step are successively performed. The surface treating that converts a surface of the substrate into a hydrophilic or hydrophobic surface is performed in the auxiliary process chamber 1210. The main treatment step is performed in the main process chamber 1130. A dry cleaning process or dry etching process is performed on the substrate in the main process chamber 1130. The film removal step is performed in the auxiliary process chamber 1210. The film removal process for removing reaction byproducts remaining on the substrate after the main treatment step may be performed in the auxiliary process chamber 1210.

According to an embodiment, the surface treating in the second treatment mode S200 is performed in the heat treatment chamber 1211 having a structure that is capable of performing a surface treatment process.

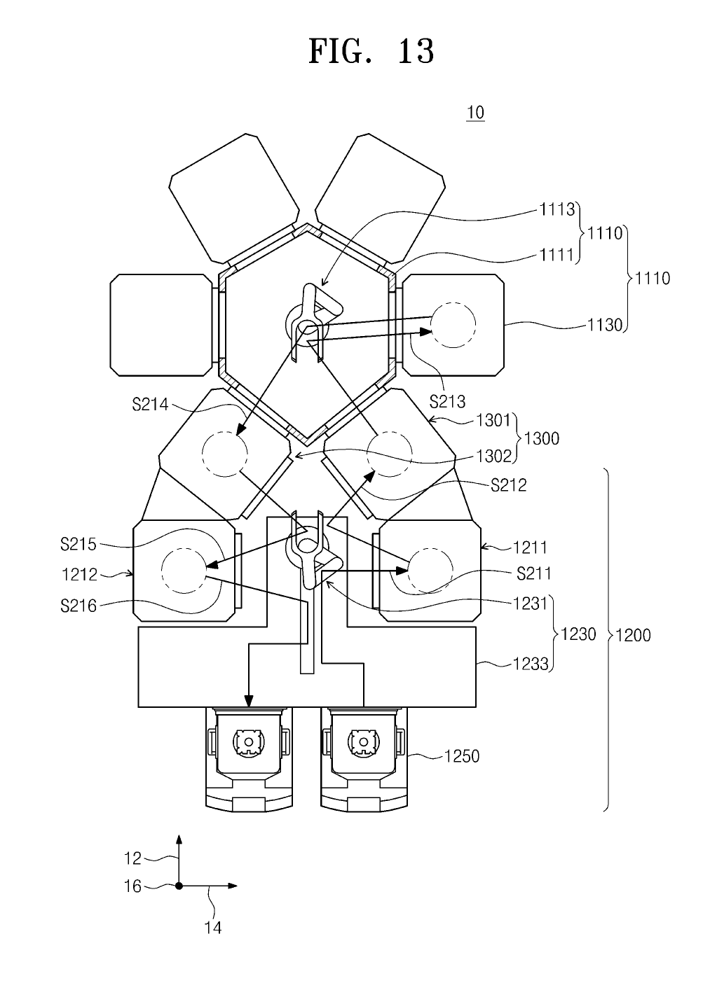

FIG. 13 is a view of a substrate transfer path in the second treatment mode S200 in the substrate treatment apparatus of FIG. 1. Hereinafter, the substrate transfer path will be described with reference to FIG. 13.

In operation S211, a substrate is transferred from a container placed on a loadport 1250 to a heat treatment chamber 1211 by an index robot 1231. A surface treatment process may be performed on the substrate in the heat treatment chamber 1211. In operation S212, the substrate is transferred from the heat treatment chamber 1211 to a buffer unit 1330 by the index robot 1231. In operation S213, the substrate is transferred from the buffer unit 1330 to a main process chamber 1130 by a transfer robot 1113. A dry cleaning process or dry etching process is performed on the substrate in the main process chamber 1130. In operation S214, the substrate is transferred to a buffer unit 1330 by the transfer robot 1113 after the main treatment step. In operation S215, the substrate is transferred from the buffer unit 1330 to an auxiliary process chamber 1210 by the index robot 1231. A film removal process for removing reaction byproducts remaining on the substrate may be performed in the auxiliary process chamber 1210. In operation S216, the substrate is transferred to the container placed on the loadport 1250 by the index robot 1231 after the film removal step.

According to another embodiment, surface treating in the second treatment mode S200 is performed in a wet treatment chamber 1212 having a structure that is capable of performing a surface treatment process.

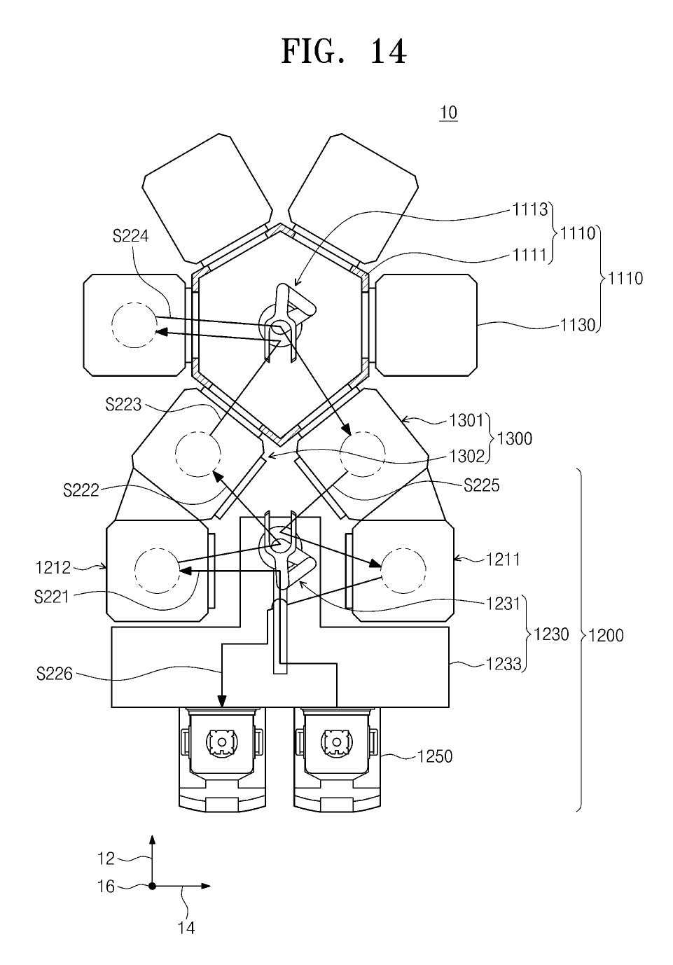

FIG. 14 is a view of a substrate transfer path in the second treatment mode S200 in the substrate treatment apparatus of FIG. 1 according to another embodiment of the present invention. Hereinafter, the substrate transfer path will be described with reference to FIG. 14.

In operation S221, a substrate is transferred from a container placed on a loadport 1250 to a heat treatment chamber 1211 by an index robot 1231. A surface treatment process may be performed on the substrate in a wet clean chamber 1212. In operation S222, the substrate is transferred from the wet clean chamber 1212 to a buffer unit 1330 by the index robot 1231. In operation S223, the substrate is transferred from the buffer unit 1330 to a main process chamber 1130 by a transfer robot 1113. A dry cleaning process or dry etching process is performed on the substrate in the main process chamber 1130. In operation S224, the substrate is transferred to a buffer unit 1330 by the transfer robot 1113 after the main treatment step. In operation S225, the substrate is transferred from the buffer unit 1330 to an auxiliary process chamber 1210 by the index robot 1231. A film removal process for removing reaction byproducts remaining on the substrate may be performed in the auxiliary process chamber 1210. In operation S226, the substrate is transferred to the container placed on the loadport 1250 by the index robot 1231 after the film removal step.

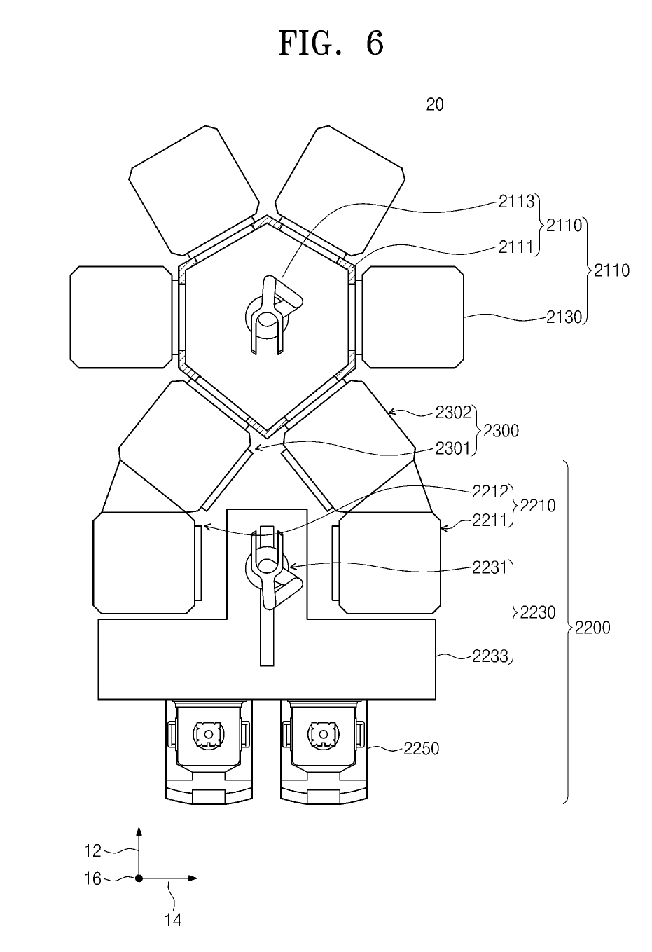

FIG. 6 is a plan view illustrating further another modified example of the substrate treatment apparatus of FIG. 1.

A substrate treatment apparatus 20 includes a process module 2100, a loadlock chamber 2300, and an index module 2200. The process module 2100, the loadlock chamber 2300, and the index module 2200 are successively arranged in a line. The process module 2100 and the loadlock chamber 2300 may be the same as the process module 1100 and the loadlock chamber 1300 of FIG. 1. The index module 2200 includes an auxiliary process chamber 2210, a transfer frame 2230, and a loadport 2250. The transfer frame 2230 and the loadport 2250 may be the same as the transfer frame 1230 and the loadport 1250 of FIG. 1. The auxiliary process chamber 2210 includes a first auxiliary process chamber 2211 and a second auxiliary process chamber 2212. Both of the first auxiliary process chamber 2211 and the second auxiliary process chamber 2212 may be provided as heat treatment chambers.

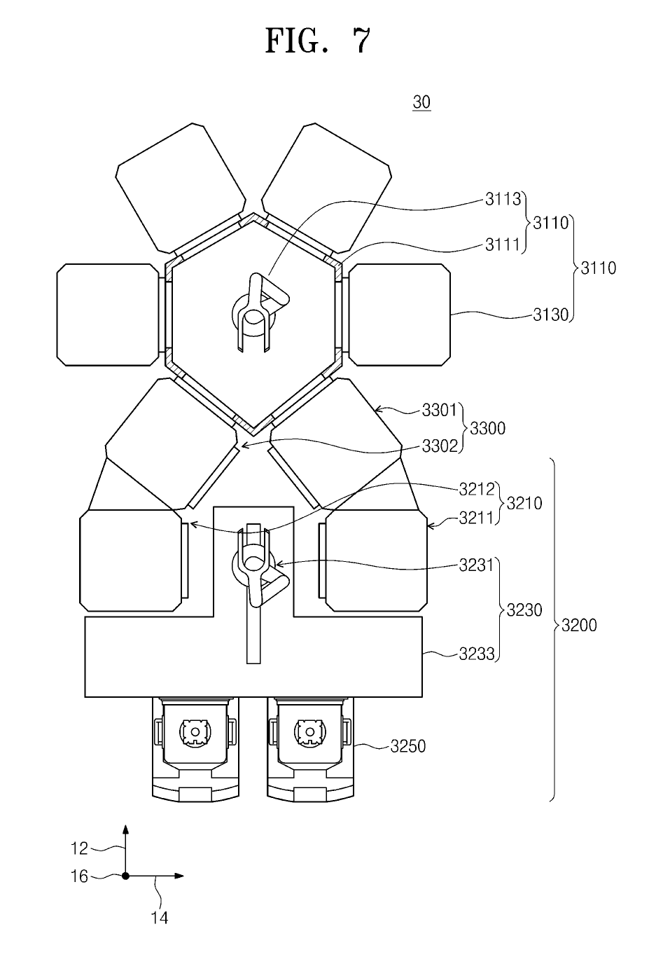

FIG. 7 is a plan view illustrating another modified example of the substrate treatment apparatus of FIG. 1.

A substrate treatment apparatus 30 includes a process module 3100, a loadlock chamber 3300, and an index module 3200. The process module 3100, the loadlock chamber 3300, and the index module 3200 are successively arranged in a line. The process module 3100 and the loadlock chamber 3300 may be the same as the process module 1100 and the loadlock chamber 1300 of FIG. 1. The index module 3200 includes an auxiliary process chamber 3210, a transfer frame 3230, and a loadport 3250. The transfer frame 3230 and the loadport 3250 may be the same as the transfer frame 1230 and the loadport 1250 of FIG. 1. The auxiliary process chamber 3210 includes a first auxiliary process chamber 3210 and a second auxiliary process chamber 3211. Both of the first auxiliary process chamber 3211 and the second auxiliary process chamber 3212 may be provided as wet clean chambers.

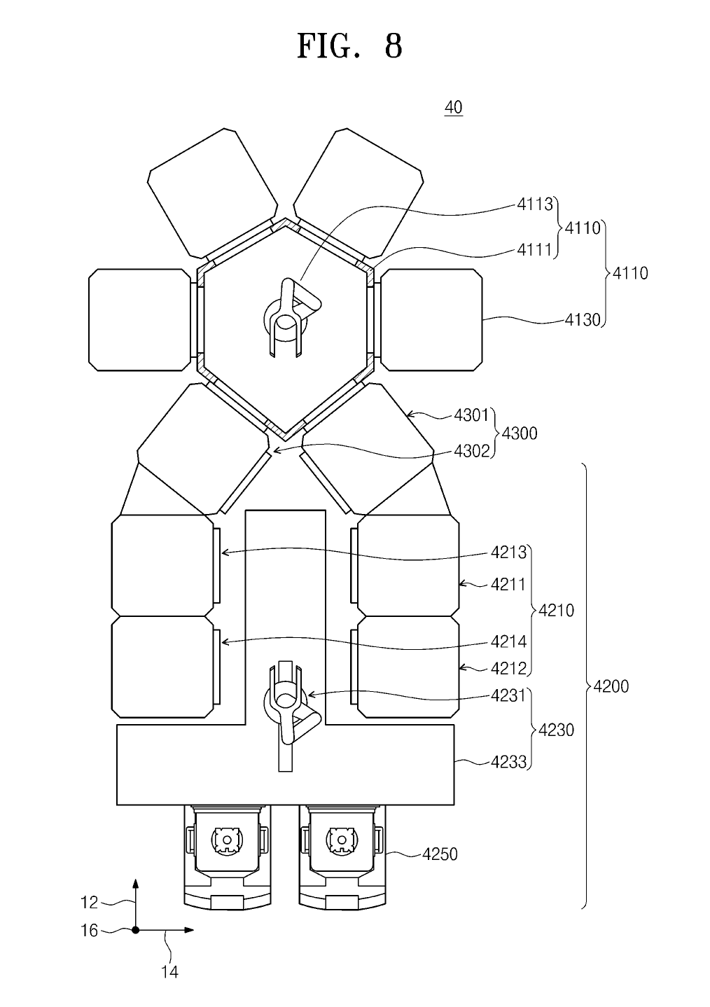

FIG. 8 is a plan view illustrating another modified example of the substrate treatment apparatus of FIG. 1.

A substrate treatment apparatus 40 includes a process module 4100, a loadlock chamber 4300, and an index module 4200. The process module 4100, the loadlock chamber 4300, and the index module 4200 are successively arranged in a line. The process module 4100 and the loadlock chamber 4300 may be the same as the process module 1100 and the loadlock chamber 1300 of FIG. 1. The index module 4200 includes an auxiliary process chamber 4210, a transfer frame 4230, and a loadport 4250. The auxiliary process chamber 4210 includes a first auxiliary process chamber 4211, a second auxiliary process chamber 4212, a third auxiliary process chamber 4213, and a fourth auxiliary process chamber 4214.

The first auxiliary process chamber 4211 and the second auxiliary process chamber 4212 are successively disposed in the first direction 12. The third auxiliary process chamber 4213 and the fourth auxiliary process chamber 4214 are successively disposed in the first direction 12. The first and second auxiliary process chambers 4211 and 4212 are disposed on one side of both side surfaces of the transfer frame 4230, and the third and fourth auxiliary process chambers 4213 and 4214 are disposed on the other side of both side surfaces of the transfer frame 4230. The first and second auxiliary process chambers 4211 and 4212 may be provided as heat treatment chambers. The third and fourth auxiliary process chambers 4213 and 4214 may be provided as wet clean chambers. According to another embodiment, the first, second, third, and fourth auxiliary process chambers 4211, 4212, 4213, and 4214 may be selectively provided as the heat treatment chamber or wet clean chamber.

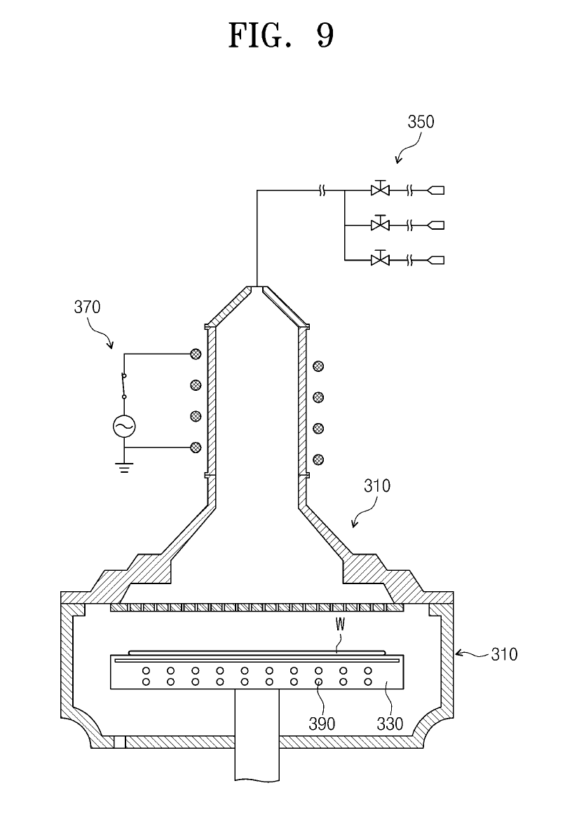

FIG. 9 is a cross-sectional view of a heat treatment chamber 300 that is provided as the auxiliary process chamber according to another embodiment of the present invention.

The heat treatment chamber 300 includes a housing 310. A substrate support unit 330 supporting a substrate is disposed within the housing 310. The housing 310 includes a gas supply unit 350 supplying a gas, a plasma source 370 generating plasma by using the supplied gas, and a heating unit 390 disposed in the support unit 330 to heat a substrate. An ashing process may be performed in the heat treatment chamber 300.

Hereinafter, a substrate treatment method using the auxiliary process chamber that is provided as the heat treatment chamber 300 of FIG. 9 in the substrate treatment apparatus of FIG. 1 according to an embodiment of the present invention will be described. According to an embodiment, a substrate is treated in a mode selected from a plurality of modes according to a state of the substrate. In the plurality of modes, treatment processes different from each other may be performed on the substrate. The plurality of modes include a first treatment mode S100, a second treatment mode S200, a third treatment mode S300, and a fourth treatment mode S400.

The first and second treatment modes S100 and S200 are the same as the first and second treatment modes S100 and S200 that are performed in the substrate treatment apparatus of FIG. 1.

The third treatment mode S300 includes an ashing step and a main treatment step. The ashing step and the main treatment step are successively performed. The ashing step is performed in an auxiliary process chamber 1210. An ashing process is performed on a substrate in the auxiliary process chamber 1210. The main treatment step is performed in the main process chamber 1130. A dry cleaning process or dry etching process is performed on the substrate in the main process chamber 1130.

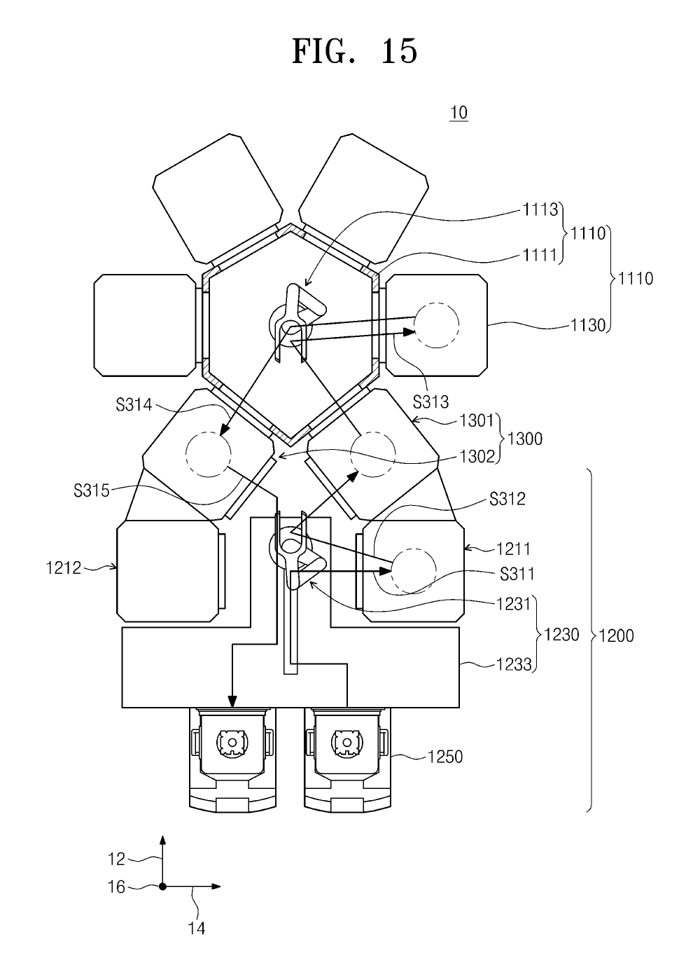

FIG. 15 is a view of a substrate transfer path in the third treatment mode S300 in the substrate treatment apparatus FIG. 1 according to an embodiment of the present invention. Hereinafter, the substrate transfer path will be described with reference to FIG. 15.

In operation S311, a substrate is transferred from a container placed on a loadport 1250 to a heat treatment chamber 1211 by an index robot 1231. An ashing process may be performed on the substrate in the heat treatment chamber 1211. In operation S312, the substrate is transferred from the heat treatment chamber 1211 to a buffer unit 1330 by the index robot 1231. In operation S313, the substrate is transferred from the buffer unit 1330 to a main process chamber 1130 by a transfer robot 1113. A dry cleaning process or dry etching process is performed on the substrate in the main process chamber 1130. In operation S314, the substrate is transferred to a buffer unit 1330 by the transfer robot 1113 after the main treatment step. In operation S315, the substrate is transferred from the buffer unit 1330 to the container placed on the loadport 1250 by the index robot 1231.

According to another embodiment, the third treatment mode S300 includes a film removal step after the main treatment step.

According to an embodiment, the film removal step in the third treatment mode S300 may be performed in a wet clean chamber 1212. A film removal process may be performed in the wet clean chamber 1212 by a wet cleaning process.

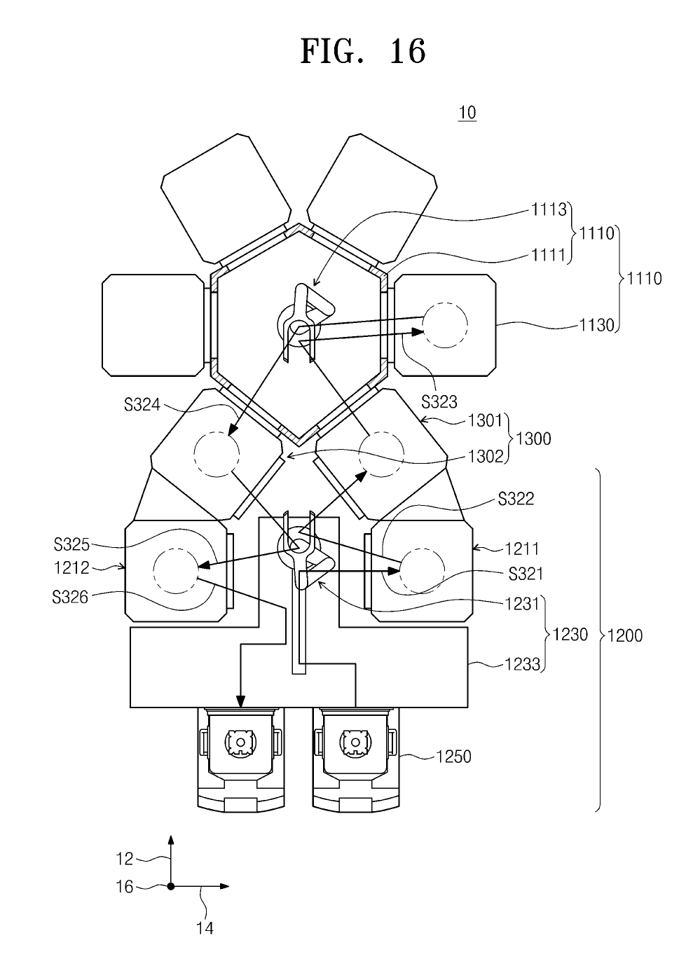

FIG. 16 is a view of a substrate transfer path in the third treatment mode S300 in the substrate treatment apparatus of FIG. 1 according to another embodiment of the present invention. Hereinafter, the substrate transfer path will be described with reference to FIG. 16.

In operation S321, a substrate is transferred from a container placed on a loadport 1250 to a heat treatment chamber 1211 by an index robot 1231. An ashing process may be performed on the substrate in the heat treatment chamber 1211. In operation S322, the substrate is transferred from the heat treatment chamber 1211 to a buffer unit 1330 by the index robot 1231. In operation S323, the substrate is transferred from the buffer unit 1330 to a main process chamber 1130 by a transfer robot 1113. A dry cleaning process or dry etching process is performed on the substrate in the main process chamber 1130. In operation S324, the substrate is transferred to a buffer unit 1330 by the transfer robot 1113 after the main treatment step. In operation S3254, the substrate is transferred from the buffer unit 1330 to a wet clean chamber 1212 by the index robot 1231. A film removal process may be performed in the wet clean chamber 1212 by a wet cleaning process. In operation S326, the substrate is transferred to the container placed on the loadport 1250 by the index robot 1231 after the film removal step.

According to another embodiment, the film removal step in the third treatment mode S300 may be performed in a heat treatment chamber 1211. A film removal process may be performed in the heat treatment chamber 1211 by a heat treatment process.

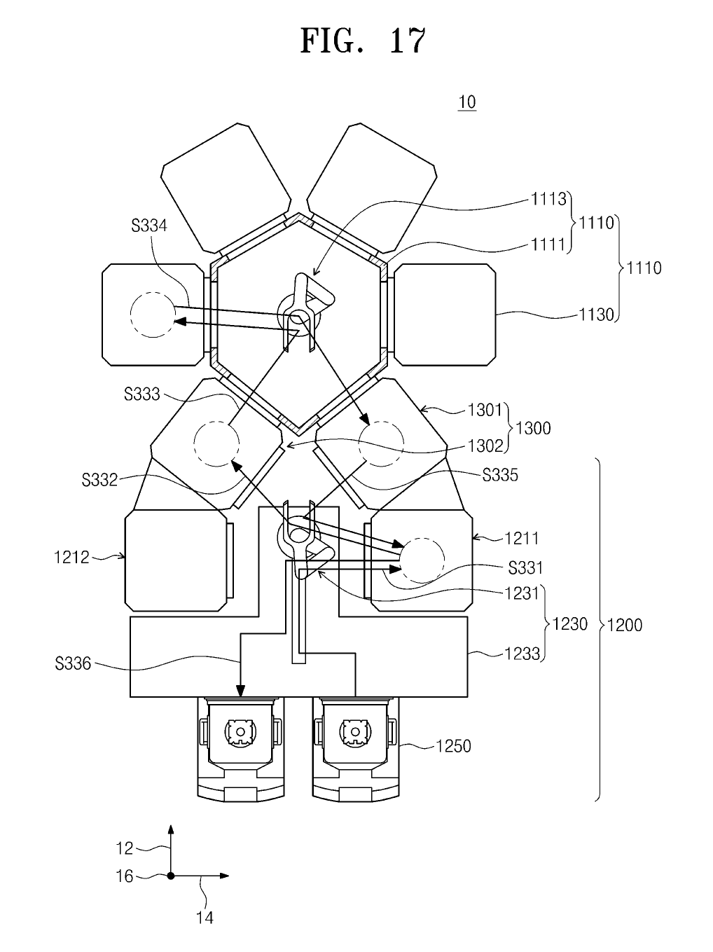

FIG. 17 is a view of a substrate transfer path in the third treatment mode S300 in the substrate treatment apparatus of FIG. 1 according to another embodiment of the present invention. Hereinafter, the substrate transfer path will be described with reference to FIG. 17.

In operation S331, a substrate is transferred from a container placed on a loadport 1250 to a heat treatment chamber 1211 by an index robot 1231. An ashing process may be performed on the substrate in the heat treatment chamber 1211. In operation S332, the substrate is transferred from the heat treatment chamber 1211 to a buffer unit 1330 by the index robot 1231. In operation S333, the substrate is transferred from the buffer unit 1330 to a main process chamber 1130 by a transfer robot 1113. A dry cleaning process or dry etching process is performed on the substrate in the main process chamber 1130. In operation S334, the substrate is transferred to a buffer unit 1330 by the transfer robot 1113 after the main treatment step. In operation S335, the substrate is transferred from the buffer unit 1330 to a heat treatment chamber 1211 by the index robot 1231. A film removal process may be performed in the heat treatment chamber 1211 by a heat treatment process. In operation S336, the substrate is transferred to the container placed on the loadport 1250 by the index robot 1231 after the film removal step.

According to another embodiment, the first treatment mode S100, the second treatment mode S200, and the third treatment mode S300 of the plurality of modes in the substrate treatment method may further include a cooling step after the main treatment step. The cooling step may be performed in a loadlock chamber 1300 by a cooling unit 1310.

A fourth treatment mode S400 includes an ashing step and a wet cleaning step. The ashing and the wet cleaning are successively performed. The ashing step is performed in a heat treatment chamber 1211. An ashing process may be performed on the substrate in a heat treatment chamber 1211. The wet cleaning step is performed in a wet clean chamber 1212. A wet cleaning process is performed on the substrate in the wet clean chamber 1212.

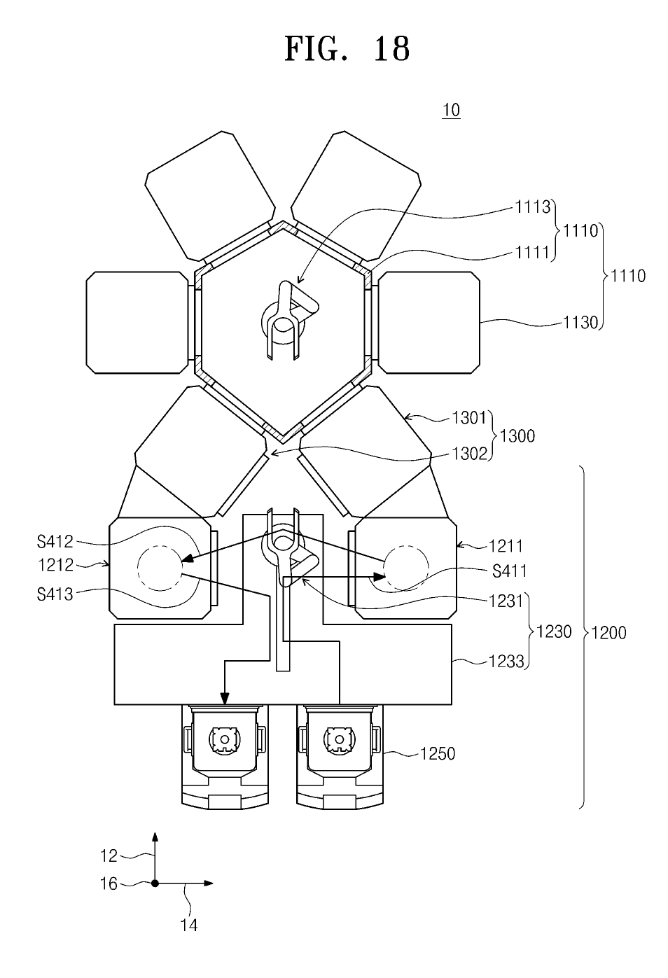

FIG. 18 is a view of a substrate transfer path in the fourth treatment mode S400 in the substrate treatment apparatus of FIG. 1 according to an embodiment of the present invention. Hereinafter, the substrate transfer path will be described with reference to FIG. 18.

In operation S411, a substrate is transferred from a container placed on a loadport 1250 to a heat treatment chamber 1211 by an index robot 1231. An ashing process may be performed on the substrate in the heat treatment chamber 1211. In operation S414, the substrate is transferred from the heat treatment chamber 1211 to a wet clean chamber 1212 by the index robot 1231. A wet cleaning process is performed on the substrate in the wet clean chamber 1212. In operation S413, the substrate is transferred to the container placed on the loadport 1250 by the index robot 1231 after the wet cleaning step.

According to the embodiments of the present invention, the index module may include the index robot, the auxiliary process chamber, and the loadport. Also, the index robot may be disposed to be accessible to the loadlock chamber, the auxiliary process chamber, and the loadport to efficiently treat the substrate.

Also, according to the embodiments of the present invention, since the substrate treatment method is performed in the mode selected from the plurality of modes according to the state of the substrate, the substrate treatment method may be efficiently performed.

The object of the present invention is not limited to the aforesaid, but other objects not described herein will be clearly understood by those skilled in the art from descriptions below.

The above detailed description exemplifies the present invention. Further, the above contents just illustrate and describe preferred embodiments of the present invention and the present invention can be used under various combinations, changes, and environments. That is, it will be appreciated by those skilled in the art that substitutions, modifications and changes may be made in these embodiments without departing from the principles and spirit of the general inventive concept, the scope of which is defined in the appended claims and their equivalents. The above-mentioned embodiments are used to describe a best mode in implementing the present invention. The present invention can be implemented in a mode other than a mode known to the art by using another invention and various modifications required a detailed application field and usage of the present invention can be made. Therefore, the detailed description of the present invention does not intend to limit the present invention to the disclosed embodiments. Further, the appended claims should be appreciated as a step including even another embodiment.

What is claimed is:

1. An apparatus for treating a substrate, comprising:
a process module comprising a main process chamber in which main treatment step is performed on the substrate;
an index module comprising a loadport on which a container for accommodating the substrate is placed, an auxiliary process chamber in which auxiliary treating is performed on the substrate, and an index robot for transferring the substrate; and
a loadlock chamber disposed between the process module and the index module,
wherein the process module, the loadlock chamber, and the auxiliary process chamber are successively disposed in a first direction, and
the index robot configured to transfer the substrate into each of the loadport, the auxiliary process chamber, and the loadlock chamber.

2. The apparatus of claim 1, wherein the index module comprises a guide lengthily disposed in the first direction, and the index robot is movable along the guide.

3. The apparatus of claim 1, wherein the main process chamber has a structure in which a dry cleaning process is capable of being performed.

4. The apparatus of claim 1, wherein the main process chamber has a structure in which a dry etching process is capable of being performed.

5. The apparatus of claim 1, wherein the loadlock chamber comprises:
a buffer unit in which the substrate stays when the substrate is transferred between the auxiliary process chamber and the process module; and
a cooling unit for cooling the substrate.

6. The apparatus of claim 5, wherein the buffer unit and the cooling unit are vertically stacked on each other.

7. The apparatus of claim 1, wherein the auxiliary process chamber comprises a heat treatment chamber in which a heat treatment process is performed on the substrate.

8. The apparatus of claim 1, wherein the auxiliary process chamber comprises a wet clean chamber in which a wet cleaning process is performed on the substrate.

9. The apparatus of claim 1, wherein the auxiliary process chamber comprises a heat treatment chamber in which an ashing process is performed on the substrate.

10. The apparatus of claim 1, wherein the auxiliary process chamber comprises:
a heat treatment chamber in which a heat treatment process is performed on the substrate; and
a wet clean chamber in which a wet cleaning process is performed on the substrate.

11. The apparatus of claim 1, wherein the auxiliary process chamber comprises:
a heat treatment chamber in which an ashing process is performed on the substrate; and
a wet clean chamber in which a wet cleaning process is performed on the substrate.

12. The apparatus of claim 1, wherein each of the loadlock chamber and the auxiliary process chamber is provided in plurality, and
the loadlock chambers are disposed on one side and the other side in the first direction with respect to the index robot, and the auxiliary process chambers are disposed on one side and the other sides in the first direction with respect to the index robot.

13. The apparatus of claim 12, wherein the loadlock chambers are arranged in a second direction perpendicular to the first direction, and
the auxiliary process chambers are arranged in the second direction.

14. The apparatus of claim 1, wherein the process module further comprising a transfer chamber in which a transfer robot for transferring the substrate is disposed, and
the main process chamber and the loadlock chamber are disposed around the transfer chamber.

15. The apparatus of claim 9, wherein the heat treatment chamber comprises:
a housing;
a substrate support unit disposed within the housing to support the substrate;
a gas supply unit supplying a gas into the housing;
a plasma source generating plasma from the gas; and
a heating unit disposed in the substrate support unit to heat the substrate.

16. An apparatus for treating a substrate, comprising:
a process module comprising a main process chamber in which main treatment step is performed on the substrate and a transfer chamber for transferring the substrate;
an index module comprising a loadport on which a container for accommodating the substrate is placed, an auxiliary process chamber in which auxiliary treating is performed on the substrate, and an index robot for transferring the substrate; and
a loadlock chamber disposed between the process module and the index module,
wherein the loadlock chamber is disposed on each of both side surfaces of the index robot,
the loadlock chamber comprises a first loadlock chamber and a second loadlock chamber,
the auxiliary process chamber comprises a first auxiliary process chamber and a second auxiliary process chamber,
the first loadlock chamber is disposed on one side of the index robot,
the second loadlock chamber is disposed on the other side of the index robot,
the first auxiliary process chamber and the first loadlock chamber disposed on the one side of the index robot are disposed in the first direction;
the second auxiliary process chamber and the second loadlock chamber disposed on the other side of the index robot are disposed in the first direction;
the first loadlock chamber, the first auxiliary process chamber, and the loadport are successively disposed in the first direction;
the second loadlock chamber, the second auxiliary process chamber, and the loadport are successively disposed in the first direction;
the index robot configured to transfer the substrate into the first loadlock chamber, the second loadlock chamber, the first auxiliary process chamber, the second auxiliary process chamber, and a container placed on the loadport,
the first auxiliary process chamber is provided as a heat treatment chamber in which a heat treatment process is performed on the substrate; and
the second auxiliary process chamber is provided as a wet clean chamber in which a wet cleaning process is performed on the substrate.

17. The apparatus of claim 16, wherein the index module comprises a guide lengthily disposed in the first direction, and the index robot is movable along the guide.

18. A method for treating a substrate by using the apparatus for treating the substrate of claim 16, the method comprising:
treating the substrate in a selected mode of a plurality of modes according to a state of the substrate,
wherein, in the plurality of modes, processes for treating the substrate are different from each other.

19. The method of claim 18, wherein the plurality of modes comprise a first treatment mode, and
the first treatment mode comprises:
a main treatment step of performing a dry cleaning process or dry etching process on the substrate in the main process chamber; and
a film removal step comprising a byproduct removal process for removing byproducts remaining on the substrate in the auxiliary process chamber after the main treatment step.

20. The method of claim 19, wherein the film removal step comprises a wet cleaning step of performing a wet cleaning process in the wet clean chamber.

21. The method of claim 19, wherein the film removal step comprises a heat treatment step of performing a heat treatment process in the heat treatment chamber.

22. The method of claim 19, wherein the film removal step comprises:
a heat treatment step of performing a heat treatment process in the heat treatment chamber; and
a wet cleaning step of performing a wet cleaning process in the wet clean chamber.

23. The method of claim 18, wherein the plurality of modes comprise a second treatment mode, and
the second treatment mode comprises:
a surface treatment step of converting a surface of the substrate into a hydrophilic or hydrophobic surface in the auxiliary process chamber;
a main treatment step of performing a dry cleaning process or dry etching process on the substrate in the main process chamber; and
a film removal step comprising a byproduct removal process for removing byproducts remaining on the substrate in the auxiliary process chamber after the main treatment step.

24. The method of claim 23, wherein the film removal step comprises a wet cleaning step of performing a wet cleaning process in the wet clean chamber.

25. The method of claim 23, wherein the film removal step comprises a heat treatment step of performing a heat treatment process in the heat treatment chamber.

26. The method of claim 23, wherein the heat treatment chamber has a structure in which a gas for converting a surface of the substrate into a hydrophilic or hydrophobic surface is supplied, and
the surface treatment step is performed in the heat treatment chamber.

27. The method of claim 23, wherein the wet clean chamber has a structure in which a chemical solution for a surface of the substrate into a hydrophilic or hydrophobic surface in the auxiliary process chamber, and
the surface treatment step is performed in the wet clean chamber.

28. The method of claim 18, wherein the auxiliary process chamber has a structure in which an ashing process is capable of being performed,
the plurality modes comprise a third treatment mode, and
the third treatment mode comprises:
an ashing step of performing an ashing process in the auxiliary process chamber; and
a main treatment step of performing a dry cleaning process or dry etching process on the substrate in the main process chamber.

29. The method of claim 28, further comprising a film removal step comprising a byproduct removal process for removing reaction byproducts remaining on the substrate in the auxiliary process chamber after the main treatment step.

30. The method of claim 18, wherein the auxiliary process chamber has a structure in which an ashing process is capable of being performed,
the plurality of modes comprise a fourth treatment mode, and
the fourth treatment mode comprises:
an ashing step of performing an ashing process in the heat treatment chamber; and
a wet cleaning step of performing a wet cleaning process in the wet cleaning chamber.

31. The method of claim 19, wherein the loadlock chamber comprises a buffer unit in which the substrate stays when the substrate is transferred and a cooling unit for cooling the substrate, and
the method further comprises cooling of the substrate in the cooling unit after the main treatment step.

32. A method for treating a substrate by using the apparatus for treating the substrate of claim 16, the method comprising:
treating the substrate in a selected mode of a plurality of modes according to a state of the substrate,
wherein the auxiliary process chamber has a structure in which an ashing process is capable of being performed,
the plurality of modes comprises at least two modes of:
a first treatment mode comprising a main treatment step of performing a dry cleaning process or dry etching process on the substrate in the main process chamber and a film removal step comprising a byproduct removal process for removing reaction byproducts remaining on the substrate in the auxiliary process chamber after the main treatment step;
a second treatment mode comprising a surface treatment step of converting a surface of the substrate into a hydrophilic or hydrophobic surface in the auxiliary process chamber, a main treatment step of performing a dry cleaning process or dry etching process on the substrate in the main process chamber, and a film removal step comprising a byproduct removal process for removing byproducts remaining on the substrate in the auxiliary process chamber after the main treatment step;
a third treatment mode an ashing step of performing an ashing process in the auxiliary process chamber and a main treatment step of performing a dry cleaning process or dry etching process on the substrate in the main process chamber; and
a fourth treatment mode comprising an ashing step of performing an ashing process in the heat treatment chamber and a wet cleaning step of performing a wet cleaning process in the wet cleaning chamber.
